(19) United States
(12) Patent Application Publication
(10) Pub. No.: US 2024/0047601 A1
(43) Pub. Date: Feb. 8, 2024

(54) PARTICLE DETECTOR COMPRISING A POROUS REGION MADE OF A SEMICONDUCTOR MATERIAL, AND ASSOCIATED MANUFACTURING METHOD

(71) Applicants: UNIVERSITE D’AIX MARSEILLE, MARSEILLE (FR); CENTRE NATIONAL DE LA RECHERCHE SCIENTIFIQUE, PARIS (FR); UNIVERSITE DE TOURS, TOURS CEDEX 1 (FR); INSA CENTRE VAL DE LOIRE, BOURGES CEDEX (FR)

(72) Inventors: Gaël GAUTIER, VERETZ (FR); Wilfried VERVISCH, LANÇON-PROVENCE (FR); Damien VALENTE, PARCAY MESLAY (FR)

(21) Appl. No.: 18/259,017

(22) PCT Filed: Dec. 22, 2021
(86) PCT No.: PCT/EP2021/087231

§ 371 Date: Jun. 22, 2023

(30) Foreign Application Priority Data
Dec. 23, 2020 (FR) FR2014090

(51) Int. Cl. H01L 31/115; H01L 31/18; H01L 31/0352

(52) U.S. Cl. CPC H01L 31/115; H01L 31/1804; H01L 31/0352; H01L 31/028

(57) ABSTRACT

A device for measuring a particle beam, includes front and rear faces, a first central portion including a device for forming a space charge region through which a particle beam to be measured passes, charge carriers of a first and second type being generated by the beam when the latter passes through the space charge region, a second peripheral portion including a device for collecting at least one type of charge carrier from the first or second type of charge carriers generated in the space charge region, the central portion having a maximum thickness less than or equal to that of the peripheral portion, the peripheral portion surrounding the central portion such that a particle beam can pass through the central portion without passing through the peripheral portion. The device includes, in a region of the central portion leading to the rear face, a layer of a porous material.

### TECHNICAL FIELD OF THE INVENTION

The technical field of the invention is that of detectors. More particularly, the invention relates to a detector, which detector is based on the so-called semiconductor technology (diode or transistor type), for measuring a particle beam.

### TECHNOLOGICAL BACKGROUND OF THE INVENTION

In experiments involving a particle beam and in particular a high-energy particle beam, it is necessary to precisely measure properties of the beam while minimising its influence on the measurement as much as possible. Usual detection technologies for beam readout are ionisation chambers, scintillators and technology based on semiconductor components provided with a rectification effect junction. It is known to measure these beams with this type of rectification effect detection, to resort to semiconductor detectors of the Schottky type, comprised of a first layer of metal and a second layer of a semiconductor material or PIN, comprised of a first layer of a p-doped semiconductor material, a second layer of an intrinsic semiconductor material and a third layer of an n-doped semiconductor material. This structure will give rise to an active zone, the one that allows the rectification effect, mainly located in the intrinsic layer in which charges will be created during the passage of the beam.

It is known to make metallic contacts acting as anode and cathode in order to collect and measure these charges. Generally speaking, these detectors are made in the thickness of a silicon plate or other semiconductor material and can reach a thickness substantially equal to 300 μm. They therefore absorb a non-negligible amount of radiation. The first consequence of this absorption is that the beam is largely disturbed during the measurement. In addition, as radiation-matter interactions take place in a large volume of the material making up the detector, degradation of the electrical and mechanical characteristics of the same can be very rapid. Finally, charges are created outside the active zone and diffuse to the electrodes, adding noise to the measurement signal. Moreover, the absorption of part of the beam in the material, which leads to energy deposits of the absorbed particles, is also the cause of an accumulation of heat energy which can bring about, depending on the temperature level, not only a deviation of the beam readout but above all the destruction of the detector.

To solve this absorption problem in part, it is known to thin the part of the detector through which the beam passes during the measurement. However, in order to collect charges generated by the beam, installation of electrodes in the beam path remains essential. The presence of these electrodes has two consequences. Firstly, the materials used to manufacture these electrodes absorb a non-negligible amount of the beam. In addition, the detector structure has to be completely included between the electrodes. But, as has been already set out, the active zone is mainly concentrated in the intrinsic zone of the semiconductor material. In other words, a large part of the material through which the beam passes does not contribute directly to the detection.

In order to overcome these drawbacks, patent application FR1654382 provides a detector in which a port has been provided in the central part of the detector in order to limit absorption of the beam measured. However, such a port weakens the detector thus obtained, making it difficult to manufacture or handle large detectors.

There is therefore a need for a detector for measuring a high-energy particle beam with good mechanical strength while avoiding excessive absorption of said beam by the detector and limiting formation of undesired charges in non-active zones.

### SUMMARY OF THE INVENTION

The invention offers a solution to the previously discussed problems by providing a detection device in which the beam passes only through the useful zone of the detector and a porous region. The porous region thus ensures good mechanical strength of the detector while minimising the amount of beam absorbed, while the rest of the structure allows collection of charges generated by the beam in the active zone in an offset manner with respect to the path of the beam to be measured.

For this, a first aspect of the invention relates to a particle beam measurement device comprising a front face and a rear face as well as:
a first part, referred to as the central part, including means for forming a space charge zone for a particle beam to be measured to pass therethrough, charge carriers of a first type and of a second type being generated by said beam when the same passes through the space charge zone;
a second part, referred to as the peripheral part, including means for collecting at least one type of charge carrier among the first type or the second type of charge carriers generated at the space charge zone;
the central part having a thickness less than or equal to the thickness of the peripheral part, the peripheral part surrounding the central part so that a particle beam can pass through the central part without passing through the peripheral part.

The device is characterised in that it includes, in a region of the central part and opening onto the rear face, a layer of a porous material forming a porous region so that the effective thickness perceived by the beam when it passes through the device at the central part by passing through the porous region along an axis normal to the front face is less than the thickness of the central part, the space charge zone preferably being situated outside the porous region.

In particular, a particle beam is understood to mean a beam of neutrons, protons, electrons or photons (for example, X-rays, gamma rays or UV rays). In other words, the notion of particles is to be taken here in its broad sense. By effective thickness, it is meant the thickness perceived by the beam as it passes through the porous medium. In other words, a porous material can be said to have an effective thickness t_{eff} if the attenuation of the beam passing through this material is equivalent to the attenuation obtained with a material of the same nature but non-porous with an effective thickness t_{eff}. It is important to note that the thickness of a porous material tₘₚ is always greater than its effective thickness t_{eff}, that is tₘₚ>t_{eff}. Indeed, the porosity makes it possible to reduce the amount of matter present in the path of the beam.

Thus, the particle beam to be measured only passes through the active zone, that is the space charge zone, preferably located outside the porous region, and the porous region of the detector. The disturbance generated by the detector on the beam is thus minimised without jeopardising the mechanical strength thereof. In addition, the reduction of interactions at the active zone and the porous region allows substantial decrease in the detector temperature related to the same.

In addition to the characteristics just discussed in the preceding paragraph, the device according to one aspect of the invention may have one or several complementary characteristics among the following, considered individually or according to all technically possible combinations.

In one embodiment, the central part is made of a wide band gap semiconductor material, preferably silicon carbide. By wide band gap, it is meant a band gap whose energy is at least twice the energy of the silicon band gap.

In one embodiment, the porous region is formed from a wide band gap semiconductor material.

In one embodiment, the space charge zone is formed using a Schottky diode, a PN diode or a PIN diode.

In one embodiment, the space charge zone of the central part is only located in a region of the central part facing the porous region.

In one embodiment, the space charge zone of the central part extends beyond the central part facing the porous region.

In one embodiment, the central part comprises:
a first layer of a semiconductor material;
a second layer of a conductive material covering the first layer;
the space charge zone being formed by the Schottky diode formed by the first layer and the second layer, the porous region being formed in the first layer.

In one embodiment, the peripheral part comprises:
a third layer of a conductive material;
a first layer of a semiconductor material covering the third layer and disposed in continuity with the first layer of the central part;
a second layer of a conductive material covering the first layer and disposed in continuity with the second layer of the central part;
the third layer of a conductive material providing collection of a first type of charge carriers generated in the charge space zone.

In one embodiment, the central part comprises:
a first layer of a semiconductor material doped with a first doping type;
a second layer of a semiconductor material doped with a second doping type opposite to the first doping type, said second layer covering the first layer;
a fourth layer of a conductive material, said fourth layer covering the second layer;
the space charge zone being formed by the PN diode formed by the first layer and the second layer, the porous region being formed in the first layer.

In one embodiment, the peripheral part comprises:
a third layer of a conductive material;
a first layer of a semiconductor material doped with a first doping type covering the third layer and disposed in continuity with the first layer of the central part; and
a second layer of a semiconductor material doped with a second doping type opposite to the first doping type covering the first layer, said second layer being disposed in continuity with the second layer of the central part; and
a fourth layer of a conductive material, said fourth layer covering the second layer, said fourth layer being disposed in continuity with the fourth layer of the central part;
the third layer of a conductive material providing collection of a first type of charge carriers generated in the space charge zone.

In one embodiment, the peripheral part comprises:
a third layer of a conductive material;
a first layer of a semiconductor material doped with a first doping type covering the third layer and disposed in continuity with the first layer of the central part, the first layer of the central part and the peripheral part having the same doping level;
a sixth layer of a dielectric material (such as an oxide or nitride, undoped glass, etc.) covering the first layer;
a fourth layer of a conductive material covering the sixth layer;
the fourth layer forming a step between the peripheral part and the central part covering a side surface of the sixth layer so as to ensure continuity between the fourth layer of the central part and the fourth layer of the peripheral part, the third layer of a conductive material providing collection of a first type of charge carriers generated in the charge space zone.

In one embodiment, the central part comprises:
a fifth layer of a semiconductor material doped with a first doping type, at least a part of the porous region being formed in the fifth layer;
a first layer of a semiconductor material doped with a first doping type, said first layer covering the fifth layer, the doping level of the fifth layer being higher than the doping level of the second layer;
a second layer of a semiconductor material doped with a second doping type opposite to the first doping type, said second layer covering the first layer;
a fourth layer of a conductive material, said fourth layer covering the second layer;
the space charge zone being formed by the PN diode formed by the fifth layer, the first layer and the second layer.

In one embodiment, the porous region is formed throughout the thickness of the fifth layer.

In one embodiment, a part of the porous region is formed in the first layer disposed in continuity with the porous region formed in the fifth layer. In other words, the porous region is formed throughout the thickness of the fifth layer and a part of the thickness of the first layer.

In one embodiment, the peripheral part comprises:
a third layer of a conductive material;
a fifth layer of a semiconductor material doped with a first doping type covering the third layer and disposed in continuity with the fifth layer of the central part; and
a first layer of a semiconductor material doped with a first doping type covering the fifth layer and disposed in continuity with the first layer of the central part, the doping level of the fifth layer being higher than the doping level of the first layer;
a second layer of a semiconductor material doped with a second doping type opposite to the first doping type covering the first layer, said second layer being disposed in continuity with the second layer of the central part;
a fourth layer of a conductive material, said fourth layer covering the second layer, said fourth layer being disposed in continuity with the fourth layer of the central part;
the third layer of a conductive material providing collection of a first type of charge carriers generated in the charge space zone.

In one embodiment, the peripheral part includes:
a third layer of a conductive material;
a fifth layer of a semiconductor material doped with a first doping type covering the third layer and disposed in continuity with the fifth layer of the central part;
a first layer of a semiconductor material doped with a first doping type covering the fifth layer and disposed in continuity with the first layer of the central part, the first layer of the central part and the peripheral part having the same doping level, the doping level of the fifth layer being higher than the doping level of the first layer;
a sixth layer of a dielectric material covering the first layer;
a fourth layer of a conductive material covering the sixth layer;
the fourth layer forming a step between the peripheral part and the central part covering a side surface of the sixth layer so as to ensure continuity between the fourth layer of the central part and the fourth layer of the peripheral part, the third layer of a conductive material providing collection of a first type of charge carriers generated in the charge space zone.

A second aspect of the invention relates to a method for manufacturing a detector, from a semiconductor substrate doped with a first doping type comprising a front face and a rear face, the manufacturing method comprising:
a step of epitaxially growing, on the front face of the substrate, a first layer of an intrinsic semiconductor material;
a step of epitaxially growing, on the front side of the substrate, a second layer of a semiconductor material doped with a second doping type opposite to the first doping type;
a step of depositing, onto the rear face of the substrate, a third layer of a conductive material;
a step of performing photolithography on the third layer of conductive material so as to provide at least a first opening within said layer; and
an etching step, at the rear face of the part of the substrate not covered in the third conductive layer so as to form a porous region in the substrate facing the first opening;
a step of depositing, onto the front side of the substrate, a fourth layer of a conductive material.

The invention and its different applications will be better understood upon reading the following description and upon examining the accompanying figures.

### BRIEF DESCRIPTION OF THE FIGURES

The figures are set forth by way of indicating and in no way limiting purposes of the invention and illustrate:

FIG. 1A a top view of a device according to one embodiment of the invention;

FIG. 1B a cross-sectional view of a device according to one embodiment of the invention;

FIG. 2A and FIG. 2B, a cross-sectional view of the structure of the device according to two alternatives of a first embodiment;

FIG. 3, a cross-sectional view of the structure of the device according to a second embodiment;

FIG. 4, a cross-sectional view of the structure of the device according to a third embodiment;

FIG. 5, a cross-sectional view of the structure of the device according to a fourth embodiment;

FIG. 6, a cross-sectional view of the structure of the device according to a fifth embodiment;

FIG. 7, a cross-sectional view of the structure of the device according to a sixth embodiment;

FIG. 8, a cross-sectional view of the structure of the device according to a seventh embodiment;

FIG. 9, a flow chart of a manufacturing method according to the invention;

FIG. 10 to FIG. 15, the different steps of the manufacturing method according to the invention.

### DETAILED DESCRIPTION

The figures are set forth by way of indicating and in no way limiting purposes of the invention. In the following, the percent porosity rate will refer to the percentage of void present in the material considered.

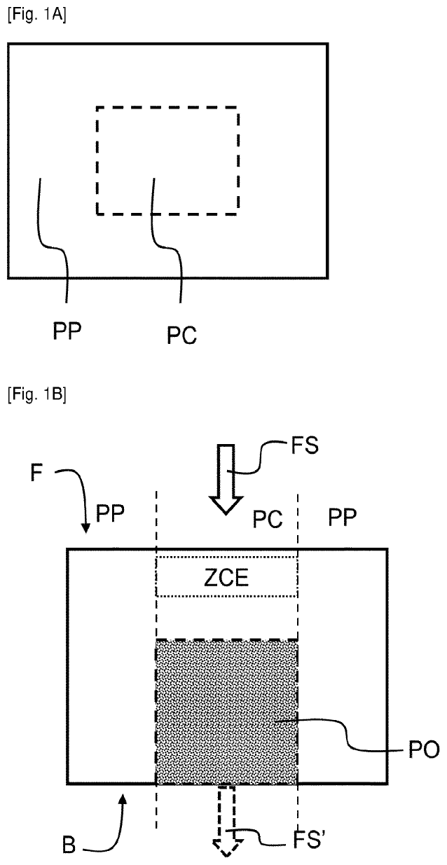

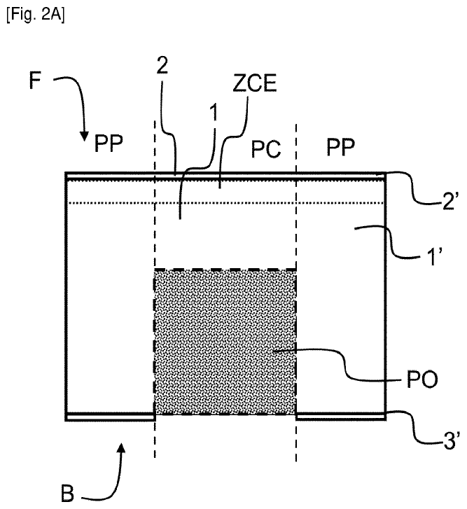

One aspect of the invention illustrated in [FIG. 1A] and [FIG. 1B] relates to a particle beam measurement device comprising a front face F and a rear face B.

The measurement device also includes a first part, referred to as the central part PC (or even the particle/electrical charge conversion zone), including means for forming a space charge zone ZCE for a particle beam FS to be measured to pass therethrough, charge carriers of a first type and of a second type being generated by said beam FS when the same passes through the space charge zone ZCE.

It also comprises a second part, referred to as the peripheral part PP (or even electric charge collection zone), including means for collecting at least one type of charge carrier among the first type or the second type of charge carriers generated at the space charge zone ZCE.

Moreover, the central part PC has a thickness less than or equal to the thickness of the peripheral part PP, the peripheral part PP surrounding the central part PC so that a particle beam FS can pass through the central part PC without passing through the peripheral part PP. The device according to the invention further includes, in a region of the central part and opening onto the rear face B, a layer of a porous material forming a porous region PO so that the effective thickness perceived by the beam FS when it passes through the device in passing through the porous region along an axis normal to the front face F is less than the thickness of the central part PC.

By effective thickness, it is meant the thickness perceived by the beam as it passes through the porous medium. In other words, a porous material can be said to have an effective thickness t_{eff} if the attenuation of the beam passing through this material is equivalent to the attenuation obtained with a material of the same nature but non-porous with an effective thickness t_{eff}. It is important to note that the thickness of a porous material tₘₚ is always greater than its effective thickness teff, that is tₘₚ>t_{eff}.

Thus, the device according to the invention makes it possible to measure a particle beam FS while minimising disturbances generated by the measurement on the output beam FS' while ensuring good mechanical strength of the device. Such a configuration makes it possible to reduce the quantity of radiation absorbed by the device and therefore the number of radiation-matter interactions likely to disturb the measurement or degrade the measurement device. In addition, the use of a porous material makes it possible to obtain an effective thickness that is less than the thickness through which the beam actually passes, which makes it possible to minimise absorption while maintaining good mechanical strength of the detector. This is particularly advantageous in the case of large detectors.

The porous region can, for example, be obtained using a method comprising a step of immersing the semiconductor material in a hydrofluoric acid-based electrolytic solution, then a step of polarising the semiconductor material so that a potential is present between both surfaces of the material.

The crystalline semiconductor material is thus etched so as to obtain a porous region. Indeed, the polarisation applied to the semiconductor material causes a current to be formed which allows a reaction with the semiconductor material and etching of the same in the form of pores of varying dimensions. In one embodiment, the pores have a diameter between 1 nm and 100 nm. The period of time of etching, the intensity of the current flowing between the electrodes, the concentration of hydrofluoric acid and additives present in the electrolyte are the main parameters determining the size of the pores, the porosity (in other words, the density of the material) and the depth of the porous region. In general, at a constant hydrofluoric acid concentration, an increase in electrical intensity results in an increase in porosity and an increase in period of time results in greater pore thicknesses. Thus, such a method for forming a porous material provides good control over the porosity of the material, which is generally between 10% and 95%.

In one embodiment, the wafer polarisation is ensured by electrodes located on the face of the wafer on which it is desired to form the porous part. In one alternative embodiment, the wafer polarisation is ensured by electrodes located on the face opposite to the face of the wafer on which it is desired to form the porous part.

It is interesting to note that, in the particular case of silicon carbide, both faces of the wafer have different properties (carbon face and silicon face). For identical etching conditions, the pore morphologies obtained are then quite different depending on the face of the etched wafer.

For more detail, the reader can refer to the thesis of Julie LASCAUD entitled “Elaboration de couches minces atténuantes en silicium poreux: Application aux transducteurs capacitifs micro-usinés”, defended in 2017, and in particular to chapter 4.3 on the configuration of electrochemical cells or G. Gautier, J. Biscarrat, D. Valente, A. Gary and F. Cayrel, Systematic study of anodic etching of highly doped n-type 4H SiC in various HF based electrolytes, J. of Electrochemical society, vol. 160, No 9, pp. D372-D379, 2013 or G. Gautier, M. Capelle, F. Cayrel, J. Billoué, P. Poveda, X. Song and J-F. Michaud, Room light anodic etching of highly doped n-type 4 H—SiC in high-concentration HF electrolytes: Difference between C and Si crystalline faces, Nanoscale Research Lett. vol. 7, pp. 367-373, 2012.

In one embodiment, the porous region PO may be circular, rectangular or square in cross-section. More generally, it may be in the form of any polygon. The size of this region is determined by the size of the beam to be measured. Preferably, the width of the beam is less than the width of the porous region. The width of the central region can therefore vary from one micron to about ten centimetres. Preferably, the entire central part PC faces the porous region PO. In other words, the dimensions of the central part PC are equal to that of the cross-section of the porous region PO.

Preferably, the central part PC is centred with respect to the entire device. The central part PC, the porous region PO and/or the peripheral part PP of the device may be made, at least in part, of a wide band gap semiconductor material, for example silicon carbide, or a semiconductor alloy comprised of elements of column III-V or II-VI. For example, when the semiconductor is silicon carbide, p-doping may be by implanting boron or aluminium atoms and n-doping by implanting nitrogen atoms.

Preferably, the space charge zone ZCE of the central part PC is only located in a region of the central part PC facing the porous region. Alternatively, the space charge zone ZCE of the central part PC extends beyond the central part PC facing the porous region.

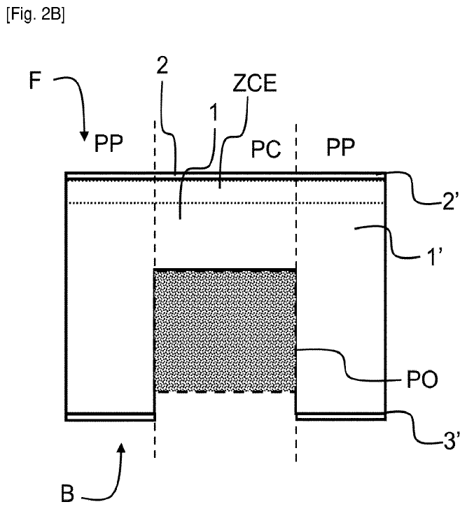

In a first embodiment illustrated in FIG. 2A, the central part PC comprises a first layer 1 of a semiconductor material; and a second layer 2 of a conductive material covering the first layer 1. In this embodiment, the space charge zone ZCE is formed by the Schottky diode formed by the first layer 1 and the second layer 2, with the porous part formed in the first layer 1.

Preferably, the porous region is between 1 and 1000 μm. Preferably, the diameter of the porous region is between 1 μm and 30 cm.

In one embodiment illustrated in FIG. 2B, the thickness of the central part PC is less than the thickness of the peripheral part PP, thus revealing a port on the rear face B at the porous region PO. In one embodiment, in order to obtain such a structure, the manufacture of the porous region is carried out in two phases: during a first phase a very high current is applied during anodising so as to achieve erosion (that is all the material is removed); during a second phase, the current is reduced so as to obtain the porous region as previously described. Thus, it is possible to modulate thicknesses of the void and the porous region in the central part PC of the device. It is worth noting that this configuration is also compatible with the embodiments that will be described in the following. In other words, regardless of the embodiment, the measurement device according to the invention may include a port at the porous region PO on the rear face B.

Preferably, in this embodiment, the peripheral part PP comprises a third layer 3 of a conductive material; a first layer 1 of a semiconductor material covering the third layer 3 and disposed in continuity with the first layer 1 of the central part PC; and a second layer 2′ of a conductive material covering the first layer 1 and disposed in continuity with the second layer 2 of the central part PC.

In this configuration, referred to as the Schottky configuration, the space charge zone ZCE is formed by the Schottky diode consisting of the first layer 1 of a conductive material and the second layer 2 of a semiconductor material. The space charge zone ZCE is thus located on the central part PC but also on the peripheral part PP. Furthermore, the third layer 3′ of a conductive material ensures collection of a first type of charge carriers generated in the space charge zone ZCE while the first layer 2,2′ made of a conductive material ensures the collection of a second type of charge carriers generated in the space charge zone ZCE. The second layer 2,2′ and the third layer 3,3′ can consist of a metal such as copper, zinc or gold or by single or multilayer graphene. Nickel, aluminium, titanium or tungsten can also be used. More generally, any conductive material suitable for the manufacturing or operating conditions of the device may be chosen. The material used for the second layer 2,2′ may be different from the material used for the third layer 3,3′. Preferably, materials used for the third layer 3′ may be selected so as to achieve an ohmic contact between the third layer 3′ and the first layer 1′ of the peripheral part PP.

Preferably, the doping level of the first layer 1 of the central part PC is identical to the doping level of the first layer 1′ of the peripheral part. This facilitates the manufacturing method as only one doping level is required.

Alternatively, the doping level of the first layer 1 of the central part PC is lower than the doping level of the first layer 1′ of the peripheral part PP. This configuration ensures better distribution of the electric field and thus allows higher voltages to be used for polarising the detector.

In one exemplary embodiment, the first layer 1,1′ has a thickness of between 500 nm and 50 microns. In one embodiment, the second layer 2, 2′ has a thickness between 10 nm and 200 nm, preferably substantially equal to 100 nm.

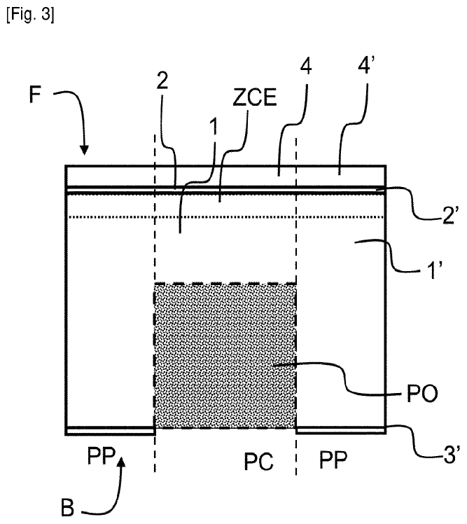

In a second embodiment of a device according to the invention illustrated in FIG. 3, the central part PC comprises a first layer 1 of a semiconductor material doped with a first doping type; a second layer 2 of a semiconductor material doped with a second doping type opposite to the first doping type, said second layer 2 covering the first layer 1; and a fourth layer 4 of a conductive material, said fourth layer 4 covering the second layer 2. In this embodiment, the space charge zone ZCE is formed by the PN diode formed by the first layer 1 and the second layer 2, the porous region being formed in the first layer 1.

Preferably, in this embodiment, the peripheral part PP comprises a third layer 3 of a conductive material; a first layer 1′ of a semiconductor material doped with a first doping type covering the third layer 3′ and disposed in continuity with the first layer 1 of the central part PC; a second layer 2′ of a semiconductor material doped with a second doping type opposite to the first doping type covering the first layer 1′, said second layer 2′ being disposed in continuity with the second layer 2 of the central part PC; and a fourth layer 4′ of a conductive material, said fourth layer 4′ covering the second layer 2′, said fourth layer 4′ being disposed in continuity with the fourth layer 4 of the part PC. In one embodiment, the doping of the first layer 1,1′ is n type and the doping of the second layer 2,2′ is p type.

In this configuration, referred to as the PN configuration, the space charge zone ZCE is formed by the PN diode consisting of the first layer 1,1 of a semiconductor material doped with a first doping type and the second layer 2,2′ of a semiconductor material doped with a second doping type opposite to the first doping type. The space charge zone ZCE is thus located on the central part PC but also on the peripheral part PP. In addition, the third layer 3′ of the peripheral part ensures collection of a first type of charge carriers generated in the space charge zone ZCE while the fourth layer 4.4′, made of a conductive material, ensures collection of a second type of charge carriers generated in the space charge zone ZCE. The third layer 3′ and the fourth layer 4.4′ can consist of a metal such as copper, zinc or gold or by single or multilayer graphene. Nickel, aluminium, titanium or tungsten can also be used. More generally, any conductive material suitable for the manufacturing or operating conditions of the device may be chosen. The material used for the third layer 3′ may be different from the material used for the fourth layer 4,4′. Preferably, materials used for the third layer 3′ may be chosen so as to achieve an ohmic contact between the third layer 3′ and the first layer 1′ of the peripheral part PP. Likewise, the materials used for the fourth layer 4,4′ may be chosen so as to obtain an ohmic contact between the fourth layer 4,4′ and the second layer 2,2′.

Preferably, the doping level of the first layer 1 of the central part PC is identical to the doping level of the first layer 1′ of the peripheral part PP. Similarly, the doping level of the second layer 2 of the central part PC is identical to the doping level of the second layer 2′ of the peripheral part. As explained previously, this facilitates the manufacturing method as only one doping level is required.

In one exemplary embodiment, the doping of the first layer 1,1′ is n type and the doping of the second layer 2,2′ is p type. The doping level of the first layer 1,1′ is between 5.10¹⁴ and 5.10¹⁹ atoms per cm³, preferably substantially equal to 5.10¹⁵ atoms per cm³. The doping level of the second layer 2,2′ is between 1.10¹⁶ and 5.10¹⁹ atoms per cm³, preferably substantially equal to 1.10¹⁹ atoms per cm³.

Alternatively, the doping level of the first layer 1 of the central part PC is lower than the doping level of the first layer 1′ of the peripheral part. Likewise, the doping level of the second layer 2 of the central part PC is lower than the doping level of the second layer 2′ of the peripheral part. As explained previously, this configuration ensures better distribution of the electric field, which allows higher voltages to be used for polarising the detector.

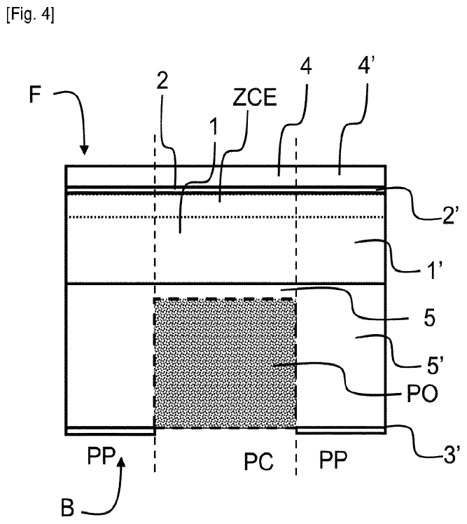

In a third embodiment illustrated in FIG. 4, the central part PC comprises a fifth layer 5 of a semiconductor material doped with a first doping type, at least part of the porous region PO being formed in the fifth layer 5; a first layer 1 of a semiconductor material doped with a first doping type on the fifth layer of a semiconductor material, the doping level of the fifth layer 5 in the central part PC being higher than the doping level of the layer 1 of the central part; a second layer 2 of a semiconductor material doped with a second doping type opposite to the first doping type, said second layer 2 covering the first layer 1; and a fourth layer 4 of a conductive material, said fourth layer 4 covering the second layer 2.

In this embodiment, the peripheral part PP thereby includes, in addition to the layers already described, a fifth layer 5′ of a semi-conductive material doped with a first doping type disposed in continuity with the fifth layer 5 of the central part PC, the doping level of the fifth layer 5′ of the peripheral part PP being higher than the doping level of the first layer 1′ of the peripheral part PP, the fifth layer 5′ being located between the third layer 3′ and the first layer 1′ of the peripheral part PP.

Thus, in this configuration referred to as PIN configuration, the PIN diode formed between the fifth layer 5,5′, the first layer 1,1′ and the first layer 2,2′ allows better recovery of charges generated in the central part PC by the beam FS of particles to be detected.

In one embodiment, the porous region PO is formed over the entire thickness of the fifth layer 5 of the central part PC. In one embodiment, a part of the porous region PO is formed in the first layer 1 in continuity with the porous region PO formed in the fifth layer 5. In other words, the porous region PO is formed throughout the thickness of the fifth layer 5 and part of the thickness of the first layer 1.

The fifth layer 5 of the peripheral part PP may, for example, be obtained from a layer covering the central part PC and the peripheral part, and in which a porous region has been formed over only part of the thickness leaving a layer at the peripheral part corresponding to the fifth layer 5′ of the peripheral part PP and a layer 5 in the central part PC of small thickness so as to ensure charge collection.

Preferably, the doping of the first layer 1,1′ and the fifth layer 5′ of the peripheral part PP is n type and the doping of the second layer 2,2′ is p type. The doping level of the fifth layer 5′ is between 1.10¹⁶ and 1.10¹⁹ atoms per cm³, preferably substantially equal to 1.10¹⁹ atoms per cm³. The doping level of the first layer 1,1′ is between 1.10¹¹ and 1.10¹⁷ atoms per cm³, preferably substantially equal to 5.10¹⁵ atoms per cm³. The doping level of the second layer 2,2′ is between 1.10¹⁶ and 5.10¹⁹ atoms per cm³, preferably substantially equal to 1.10¹⁹ atoms per cm³.

In one exemplary embodiment, the first layer 1,1′ has a thickness of between 500 nm and 50 microns; the second layer 2,2′ has a thickness of between 50 and 200 nm, preferably substantially equal to 100 nm; and the fifth layer has a thickness of between 250 and 350 microns, preferably substantially equal to 300 microns.

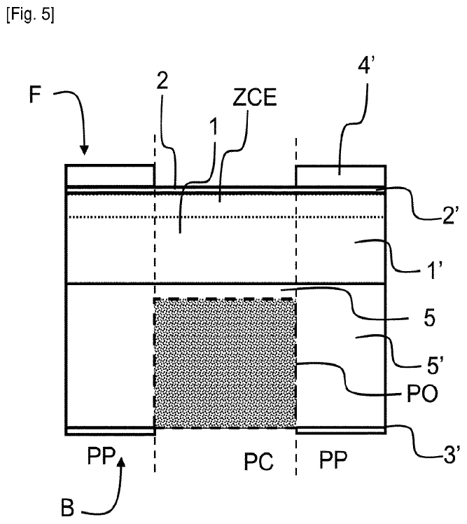

Since the beam to be measured only passes through the detector at the central part PC, it may be advantageous to offset all of the electrodes necessary for the recovery of the charge carriers at the peripheral part. For this, in a fourth embodiment illustrated in FIG. 5, the central part PC comprises a first layer 1 of a semiconductor material doped with a first doping type and a second layer 2 of a semiconductor material doped with a second doping type opposite to the first doping type, said second layer 2 covering the first layer 1. The central part is thus devoid of an electrode in this embodiment. In this embodiment, the space charge zone is also produced by the PN diode consisting of the first layer 1,1′ of a semiconductor material doped with a first doping type and the second layer 2,2′ of a semiconductor material doped with a second doping type opposite to the first doping type. In contrast, charge carriers are recovered only at the peripheral part by the third layer 3′ and fourth layer 4′ of the peripheral part PP. In this configuration, the beam only passes through the first layer 1 and the second layer 2 of the central part at which the charge space zone is formed. In this embodiment, the fourth layer 4′ is only on the peripheral part and thus forms a port O1.

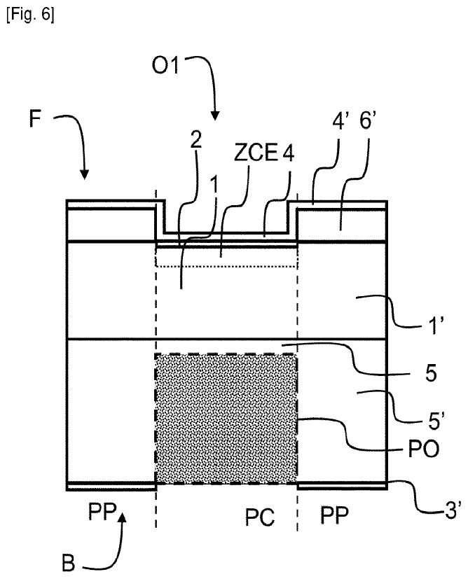

In the previous embodiment, the space charge zone ZCE is present in both the central part PC and the peripheral part PP of the device. However, it may be advantageous to have a space charge zone ZCE only in the central part PC of the detection device. For this, in a fifth embodiment illustrated in FIG. 6, the peripheral part PP comprises a third layer 3′ of a conductive material; a first layer 1′ of a semiconductor material doped with a first doping type covering the third layer 3′ and disposed in continuity with the first layer 1 of the central part PC; a sixth layer 6′ of a dielectric material covering the first layer 1′; and a fourth layer 4′ of a conductive material covering the sixth layer 6′. Thus, since the second layer 2,2 is present only in the central part PC of the device, the space charge zone ZCE is also restricted to the central part PC of the device.

In this embodiment, the fourth layer 4, 4′ forms a step between the peripheral part PP and the central part PC covering a side surface of the sixth layer 6′ so as to ensure continuity between the fourth layer 4 of the central part PC and the fourth layer 4′ of the peripheral part PP. In this embodiment, the sixth layer 6′ is only on the peripheral part and thus forms a port O1.

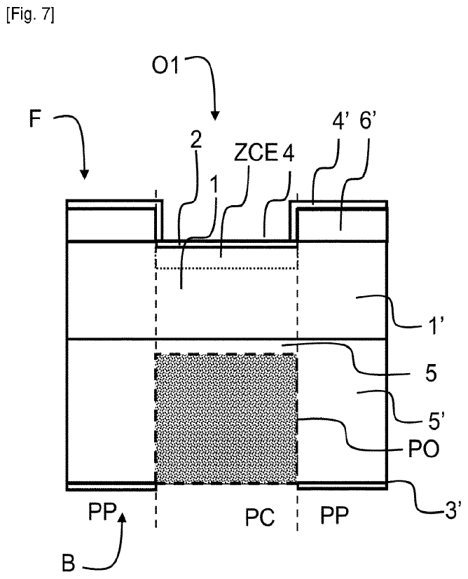

However, in the previous embodiment, the fourth layer 4′ of the central part PC covers the entire central part PC through which the beam to be measured passes. It may be advantageous in some situations to reduce this absorption phenomenon. To this end, in a sixth embodiment illustrated in FIG. 7, the fourth layer 4′ of the central part PC covers only a part of the central part PC.

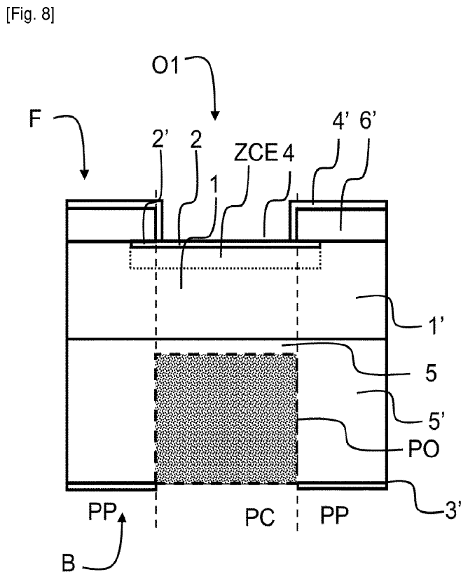

Furthermore, when the extent of the second layer 2,2′ is limited to the central part PC, the MIS (Metal Insulator Semi-Conductor) structure constituted at the peripheral part PP of the device formed by the first layer of the peripheral part 1′, the sixth layer of the peripheral part 6′ and by the fourth layer 4′ of the peripheral part may disturb the measurement, in particular by inducing capacitive effects. In order to prevent this phenomenon, in a seventh embodiment illustrated in FIG. 8, the second layer 2′ of the peripheral part only partially covers the first layer 1′ of the peripheral part while ensuring continuity with the second layer 2 of the central part PC. In other words, the second layer 2,2′ is present throughout the central part PC of the device as well as in a zone of the peripheral part PP. The presence of the second layer 2 over a larger zone than the central part PC limits formation of the previously discussed MIS structure. This reduces the capacitive phenomena between the first layer of the peripheral part 1′, the sixth layer of the peripheral part 6′ and the fourth layer 4′ of the peripheral part.

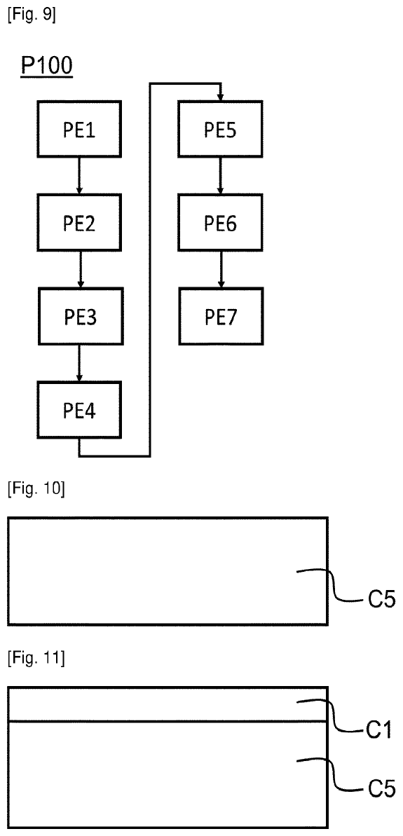

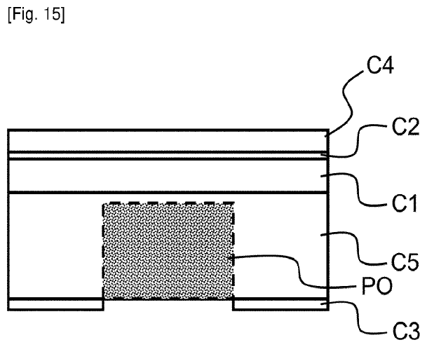

In order to obtain a device according to a first aspect of the invention, a second aspect of the invention illustrated in [FIG. 9] to [FIG. 15] relates to a manufacturing method P100. As illustrated in [FIG. 10], this fabrication is carried out from a substrate C5 having doping of a first type, for example n type. The substrate is for forming the fifth layer 5,5′ of the central part PC and the peripheral part PP of the device according to a first aspect of the invention. Preferably, the substrate C5 is an n-doped SIC-4H type substrate, the doping level preferably being between 5.10¹⁷ and 5.10¹⁸ at·cm⁻³, for example equal to 10¹⁸ at·cm⁻³. Preferably, this doping is a nitrogen atom doping.

As illustrated in [FIG. 11], the method P100 according to a second aspect of the invention comprises a step PE1 of epitaxially growing, on the front face of the substrate C5, a first layer C1 of an intrinsic semiconductor material. In other words, no doping step is carried out on this layer C1. This first layer C1 is for forming the first layer 1,1′ of the central part PC and the peripheral part PP of the device.

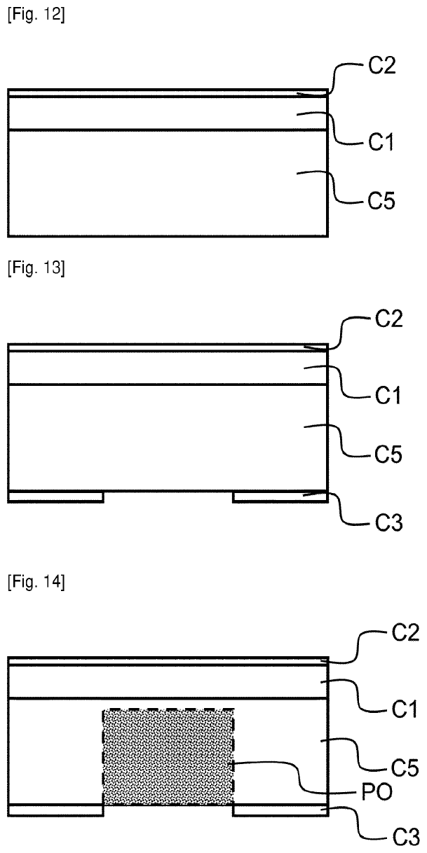

As illustrated in [FIG. 12], the method P100 then comprises a step PE2 of epitaxially growing, on the front face of the substrate C5, a second layer C2 of a semiconductor material doped with a second doping type opposite to the first doping type, for example a p-type doping. Preferably, the doping of the second layer 02 is between 5.10¹⁷ and 5.10¹⁸ at·cm⁻³, for example equal to 10¹⁸ at·cm⁻³. Preferably, this doping is an aluminium atom doping. This second layer C2 is for forming the second layer 2,2′ of the central part PC and the peripheral part PP of the device.

The method P100 then comprises a step PE3 of depositing, onto the rear face of the substrate C5, a third layer C3 of a conductive material, for example a layer of titanium or aluminium. This third layer C3 is for forming the third layer 3′ of the peripheral part of the device. The method also includes a step PE4 of performing photolithography on the third layer C3 of a conductive material so as to provide at least one first opening within said layer C3. The structure obtained at the end of these two steps PE3, PE4 is illustrated in [FIG. 13].

As illustrated in [FIG. 14], the method P100 also includes an etching step PE5, at the rear face of the part of the substrate C5 not covered in the third conductive layer C3 so as to form a porous region PO in the substrate C5 facing the first opening.

In one embodiment, the substrate C5 is a SiC substrate. In this embodiment, the etching step PE5 is carried out using a hydrofluoric acid and ethanol based solution having a concentration of between 5 and 30% by volume (that is the volume ratio between hydrofluoric acid and ethanol ranges from 5 to 30% total volume of the solution). In one embodiment, the etching step PE5 is performed by applying an electrolysis current with a current density of between 10 mA/cm² and 80 mA/cm² for a period of time of about 15 to 120 minutes. In one embodiment, the current density is adjusted during etching so as to obtain a porous region PO with a variable degree of porosity depending on the depth of the porous region PO. For further detail related to this etching step PE5, the reader may refer to the thesis of Julie LASCAUD entitled “Elaboration de couches minces atténuantes en silicium poreux: Application aux transducteurs capacitifs micro-usinés” already cited.

As illustrated in [FIG. 15], the method P100 includes a step PE6 of depositing, onto the front face of the substrate C5, a fourth layer C4 of a conductive material, for example a layer of titanium or aluminium. This fourth layer C4 is for forming the fourth layer 4,4′ of the central part PC and the peripheral part PP of the device.

In one embodiment, the deposition step PE6 is preceded by a step of depositing a passivation layer onto the front face of the substrate C5 and a lithography step so as to define the region or regions in which the fourth layer C4 of a conductive material will be deposited. This passivation layer is for forming the sixth layer 6′ of the peripheral part of the device, the region or regions opened during the lithography step hence corresponding to the peripheral part PP of the device. In one embodiment, the passivation layer is obtained by depositing an oxide.

1. A device for measuring a particle beam comprising a front face and a rear face as well as:
a first part forming a central part, including means for forming a space charge zone for a particle beam to be measured to pass therethrough, charge carriers of a first type and of a second type being generated by said particle beam when the particle beam passes through the space charge zone;
a second part forming a peripheral part, including means for collecting at least one type of charge carrier among the first type or the second type of charge carriers generated at the space charge zone;
the central part having a thickness less than or equal to a thickness of the peripheral part, the peripheral part surrounding the central part so that a particle beam can pass through the central part without passing through the peripheral part, the device further including, in a region of the central part and opening onto the rear face, a layer of a porous material forming a porous region so that an effective thickness perceived by the particle beam when the particle beam passes through the device at the central part by passing through the porous region along an axis normal to the front face is less than the thickness of the central part, the space charge zone being situated outside the porous region.

2. The measurement device according to claim 1, wherein the central part is made of a wide band gap semiconductor material.

3. The measurement device according to claim 2, wherein the semiconductor is silicon carbide.

4. The measurement device according to claim 1, wherein the space charge zone is formed by a Schottky diode, a PN diode or a PIN diode.

5. The measurement device according to claim 1, wherein the space charge zone of the central part is only located in a region of the central part facing the porous region.

6. The measurement device according to claim 1, wherein the space charge zone of the central part extends beyond the central part facing the porous region.

7. The measurement device according to claim 1, wherein the central part comprises:
a first layer of a semiconductor material;
a second layer of a conductive material covering the first layer, and
the space charge zone being formed by the Schottky diode formed by the first layer and the second layer, the porous region being formed in the first layer.

8. The measurement device according to claim 7, wherein the peripheral part comprises:
a third layer of a conductive material;
a first layer of a semiconductor material covering the third layer and disposed in continuity with the first layer of the central part; and
a second layer of a conductive material covering the first layer and disposed in continuity with the second layer of the central part, and
the third layer of a conductive material ensuring collection of a first type of charge carriers generated in the charge space zone.

9. The measurement device according to claim 5, wherein the central part comprises:
a first layer of a semiconductor material doped with a first doping type;
a second layer of a semiconductor material doped with a second doping type opposite to the first doping type, said second layer covering the first layer;
a fourth layer of a conductive material, said fourth layer covering the second layer, and
the space charge zone being formed by the PN diode formed by the first layer and the second layer, the porous region being formed in the first layer.

10. The measurement device according to claim 9, wherein the peripheral part comprises:
a third layer of a conductive material;
a first layer of a semiconductor material doped with a first doping type covering the third layer and disposed in continuity with the first layer of the central part; and
a second layer of a semiconductor material doped with a second doping type opposite to the first doping type covering the first layer, said second layer being disposed in continuity with the second layer of the central part;
a fourth layer of a conductive material, said fourth layer covering the second layer, said fourth layer being disposed in continuity with the fourth layer of the central part, and
the third layer of a conductive material ensuring collection of a first type of charge carriers generated in the charge space zone.

11. The measurement device according to claim 9, wherein the peripheral part comprises:
a third layer of a conductive material;
a first layer of a semiconductor material doped with a first doping type covering the third layer and disposed in continuity with the first layer of the central part, the first layer of the central part and of the peripheral part having the same doping level;
a sixth layer of a dielectric material covering the first layer;
a fourth layer of a conductive material covering the sixth layer, and
the fourth layer forming a step between the peripheral part and the central part covering a side surface of the sixth layer so as to ensure continuity between the fourth layer of the central part and the fourth layer of the peripheral part, the third layer of a conductive material ensuring collection of a first type of charge carriers generated in the charge space zone.

12. The device according to claim 5, wherein the central part comprises:
a fifth layer of a semiconductor material doped with a first doping type, at least part of the porous region being formed in the fifth layer;
a first layer of a semiconductor material doped with a first doping type, said first layer covering the fifth layer, the doping level of the fifth layer being higher than the doping level of the layer;
a second layer of a semiconductor material doped with a second doping type opposite to the first doping type, said second layer covering the first layer;
a fourth layer of a conductive material, said fourth layer covering the second layer, and
the space charge zone being formed by the PIN diode formed by the fifth layer, the first layer and the second layer.

13. The device according to claim 12, wherein the peripheral part comprises:
a third layer of a conductive material;
a fifth layer of a semiconductor material doped with a first doping type covering the third layer and disposed in continuity with the fifth layer of the central part;
a first layer of a semiconductor material doped with a first doping type covering the fifth layer and disposed in continuity with the first layer of the central part, the doping level of the fifth layer being higher than the doping level of the first layer;
a second layer of a semiconductor material doped with a second doping type opposite to the first doping type covering the first layer, said second layer being disposed in continuity with the second layer of the central part;
a fourth layer of a conductive material, said fourth layer covering the second layer, said fourth layer being disposed in continuity with the fourth layer of the central part, and
the third layer of a conductive material ensuring collection of a first type of charge carriers generated in the charge space zone.

14. The device according to claim 12, wherein the peripheral part includes:
a third layer of a conductive material;
a fifth layer of a semiconductor material doped with a first doping type covering the third layer and disposed in continuity with the fifth layer of the central part;
a first layer of a semiconductor material doped with a first doping type covering the fifth layer and disposed in continuity with the first layer of the central part, the first layer of the central part and the peripheral part having the same doping level, the doping level of the fifth layer being higher than the doping level of the first layer;
a sixth layer of a dielectric material covering the first layer, and
a fourth layer of a conductive material covering the sixth layer;
the fourth layer forming a step between the peripheral part and the central part covering a side surface of the sixth layer so as to ensure continuity between the fourth layer of the central part and the fourth layer of the peripheral part, the third layer of a conductive material providing collection of a first type of charge carriers generated in the charge space zone.

15. A method for manufacturing a detector according to claim 1, from a semiconductor substrate doped with a first doping type comprising a front face and a rear face, the manufacturing method comprising:
epitaxially growing, on the front face of the substrate, a first layer of an intrinsic semiconductor material;
epitaxially growing, on the front face of the substrate, a second layer of a semiconductor material doped with a second doping type opposite to the first doping type;
depositing, onto the rear face of the substrate, a third layer of a conductive material;
performing photolithography on the third layer of a conductive material so as to provide at least one first opening within said layer; and
etching, at the rear face of the part of the substrate not covered in the third conductive layer so as to form a porous region in the substrate facing the first opening, and
depositing, onto the front face of the substrate, a fourth layer of a conductive material.
